(19) United States
(12) Patent Application Publication
(10) Pub. No.: US 2014/0027727 A1
(43) Pub. Date: Jan. 30, 2014

(54) ORGANIC LIGHT EMITTING DEVICES AND METHODS OF FABRICATING THE SAME

(71) Applicant: ELECTRONICS AND TELECOMMUNICATIONS RESEARCH INSTITUTE, Daejeon (KR)

(72) Inventors: Bong Joon LEE, Chungcheongbuk-do (KR); Doo-Hee Cho, Daejeon (KR); Jaehyun Moon, Daejeon (KR); Seung Koo Park, Daejeon (KR); Jeong Ik Lee, Gyeonggi-do (KR); Hye Yong Chu, Daejeon (KR); Jin Wook Shin, Incheon (KR); Nam Sung Cho, Daejeon (KR); Jin Woo Huh, Daejeon (KR); Joon Tae Ahn, Daejeon (KR); Jun-Han Han, Daejeon (KR); Chul Woong Joo, Seoul (KR); Joo Hyun Hwang, Seoul (KR)

(73) Assignee: Electronics and Telecommunications Research Institute, Daejeon (KR)

(21) Appl. No.: 13/746,816

(22) Filed: Jan. 22, 2013

(30) Foreign Application Priority Data
Jul. 30, 2012 (KR) 10-2012-0083401

(51) Int. Cl. H01L 51/52; H01L 51/56

(52) U.S. Cl. CPC H01L 51/5281; H01L 51/56
USPC 257/40; 438/29

(57) ABSTRACT

Disclosed are organic light emitting devices and methods of fabricating the same. The organic light emitting device may include light scattering parts having irregular island-shapes irregularly arranged. The organic light emitting device may further include a planarization layer, a first electrode, an organic light emitting layer, a second electrode, and an encapsulation layer. The light scattering parts may be formed using an organic solution having a low refractive index to improve light extraction efficiency of the organic light emitting device. Additionally, the light scattering parts of the irregular island-shapes may improve the light extraction efficiency of lights of all wavelengths, so as to be applied to an organic white light emitting device. The light scattering parts of the irregular island-shapes may be formed using the organic solution by a dewetting phenomenon. The light scattering parts may be formed at a temperature of about 250 degrees Celsius or less.

### CROSS-REFERENCE TO RELATED APPLICATIONS

This U.S. non-provisional patent application claims priority under 35 U.S.C. §119 to Korean Patent Application No. 10-2012-0083401, filed on Jul. 30, 2012, the entirety of which is incorporated by reference herein.

### BACKGROUND

The inventive concept relates to light emitting devices and, more particularly, to organic light emitting devices and methods of fabricating the same.

Organic light emitting devices (OLED) may be self-light emitting devices emitting light by organic light emitting materials electrically excited. The OLEDs may emit light having one of various colors according to a kind of material consisting of an organic light emitting layer. The OELDs may have excellent display characteristics such as wide view angle, high response speed, thinness, low manufacture costs. The OELDs are attractive in next generation flat panel display devices and lightning. However, conventional OELDs may have a low external light emitting efficiency of about 20% or less.

### SUMMARY

Embodiments of the inventive concept may provide organic light emitting devices including light scattering parts having a low refractive index and irregular island-shapes.

Embodiments of the inventive concept may also provide methods of fabricating an organic light emitting device by a dewetting phenomenon at a low temperature.

In one aspect, an organic light emitting device may include: a substrate including a first surface and a second surface opposite to each other and having a first refractive index; light scattering parts disposed on the first surface of the substrate and having a second refractive index; a planarization layer disposed on the light scattering parts and having a third refractive index; a first electrode disposed on the planarization layer; an organic light emitting layer disposed on the first electrode; a second electrode disposed on the organic light emitting layer; and an encapsulation layer disposed on the second electrode. The light scattering parts may have irregular island-shapes irregularly arranged; and the second refractive index may be smaller than each of the first refractive index and the third refractive index.

In some embodiments, the organic light emitting device may further include: antireflective parts disposed on the second surface of the substrate. The antireflective parts may have a refractive index smaller than the first refractive index; the antireflective parts may have irregular island-shapes irregularly arranged; and the island-shapes of the antireflective parts may include at least one of a hemisphere-shape, a pillar-shape, an ellipse-shape, and/or a capsule-shape.

In other embodiments, the antireflective parts may include a polyfluorine-based material.

In still other embodiments, the light scattering parts may include a polyfluorine-based material.

In even other embodiments, the first electrode may have a greater refractive index than the organic light emitting layer; and the third refractive index may be greater than the refractive index of the first electrode.

In yet other embodiments, an average diameter of the light scattering parts may have a range of about 100 nm to about 1000 nm.

In another aspect, a method of fabricating an organic light emitting device may include: coating an organic solution including an organic material and a photo cross-linking agent on a first surface of a substrate to form an organic layer; thermally treating the organic layer to irregularly form light scattering parts of island-shapes on the first surface of the substrate; and crosslinking the light scattering parts.

In some embodiments, the method may further include: forming a planarization layer on the crosslinked light scattering parts.

In other embodiments, the method may further include: sequentially stacking a first electrode, an organic light emitting layer, a second electrode, and an encapsulation layer on the planarization layer.

In still other embodiments, forming the planarization layer may include: spin-coating a precursor on the crosslinked light scattering parts; and crosslinking the spin-coated precursor by a thermal or UV exposure process.

In even other embodiments, the method may further include: forming antireflective parts on a second surface opposite to the first surface of the substrate.

In yet other embodiments, forming the antireflective parts may include: coating an organic solution including an organic material and a photo cross-linking agent on the second surface of a substrate to form an organic layer; thermally treating the organic layer disposed on the second surface to irregularly form antireflective parts of island-shapes on the second surface of the substrate; and crosslinking the antireflective parts.

In yet still other embodiments, the organic material may have a hydrophobic property; the substrate may have a hydrophilic property; and the light scattering parts may be formed using a dewetting phenomenon of the hydrophobic organic material and the hydrophilic substrate.

In further embodiments, the light scattering parts may be formed by a thermal treating process performed at a temperature of about 250° C. or less.

In still another aspect, a method of fabricating an organic light emitting device may include: providing a substrate including a first surface and a second surface opposite to each other; sequentially stacking a first electrode, an organic light emitting layer, a second electrode, and an encapsulation layer on the first surface of the substrate; and forming antireflective parts on the second surface of the substrate. Forming the antireflective parts may include: coating an organic solution including an organic material and a photo cross-linking agent on the second surface of a substrate to form an organic layer; thermally treating the organic layer to irregularly form antireflective parts of island-shapes on the second surface of the substrate; and crosslinking the antireflective parts.

In some embodiments, the organic material may include a polyfluorine-based material.

In other embodiments, the antireflective parts may be formed by a thermal treating process performed at a temperature of about 250° C. or less.

In still other embodiments, the organic material may have a hydrophobic property; the substrate may have a hydrophilic property; and the antireflective parts may be formed using a dewetting phenomenon of the hydrophobic organic material and the hydrophilic substrate.

### BRIEF DESCRIPTION OF THE DRAWINGS

The inventive concept will become more apparent in view of the attached drawings and accompanying detailed description.

FIG. 1 is a cross-sectional view illustrating an organic light emitting device according to some embodiments of the inventive concept;

FIG. 2 is a scanning electron microscopy (SEM) photograph of light scattering parts disposed on a substrate according to some embodiments of the inventive concept;

FIG. 3 is an atomic force microscopy (AFM) image of light scattering parts disposed on a substrate according to some embodiments of the inventive concept;

FIG. 4 is a cross-sectional view illustrating an organic light emitting device according to other embodiments of the inventive concept;

FIG. 5 is a flowchart illustrating a method of fabricating light scattering parts according to a first embodiment of the inventive concept;

FIGS. 6A, 6B, and 6C are cross-sectional views illustrating a method of fabricating light scattering parts according to a first embodiment of the inventive concept;

FIG. 7 is a flowchart illustrating a method of fabricating light scattering parts according to a second embodiment of the inventive concept;

FIG. 8 is a cross-sectional view illustrating a method of forming a planarization layer according to some embodiments of the inventive concept;

FIG. 9 is a flowchart illustrating a method of fabricating light scattering parts according to a third embodiment of the inventive concept;

FIG. 10 is a cross-sectional view illustrating a method of fabricating light scattering parts according to a third embodiment of the inventive concept; and

FIG. 11 is a flowchart illustrating a method of fabricating light scattering parts according to a fourth embodiment of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Hereinafter, organic light emitting devices according to embodiments of the inventive concept will be described with reference to the drawings.

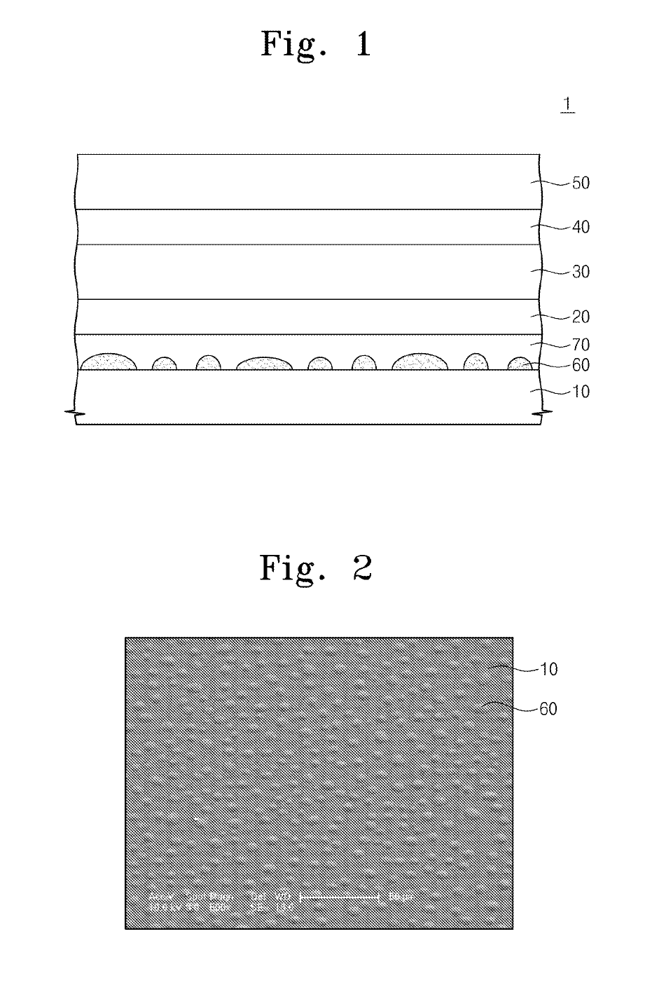

FIG. 1 is a cross-sectional view illustrating an organic light emitting device according to some embodiments of the inventive concept.

Referring to FIG. 1, an organic light emitting device 1 may include light scattering parts 60 having irregular island-shapes, a planarization layer 70, a first electrode 20, an organic light emitting layer 30, a second electrode 40, and a encapsulation layer 50 which are disposed on a substrate 10.

The substrate 10 may transmit light. In some embodiments, the substrate 10 including silicon oxide (SiO₂) may have an refractive index within a range of about 1.4 to about 1.5.

The light scattering parts 60 may be disposed on the substrate 10. The light scattering parts 60 may be provided between the substrate 10 and the first electrode 20. The light scattering parts 60 may include an organic material having a low refractive index. The organic material may be an oligomer or polymer including fluorine (e.g., a polyfluorine-based material). For example, the organic material may include at least one of poly(1,1,1,3,3,3-hexafluoroisopropyl acrylate), poly(2,2,3,3,4,4,4-heptafluorobutyl acrylate), poly(2,2,3,3,4,4,4-heptagluorobutyl methacrylate), poly(2,2,3,3,3-pentafluoropropyl acrylate), poly(1,1,1,3,3,3-hexafluoroisopropyl methacrylate), poly(2,2,3,4,4,4-hexafluorobutyl acrylate), poly(2,2,3,4,4,4-hexafluorobutyl methacrylate), poly(2,2,3,3,3-pentafluoropropyl methacrylate), poly(2,2,2-trifluropropyl methacrylate), poly(2,2,2-trifluoroethyl acrylate), poly(2,2,3,3-tetrafluoropropryl acrylate), poly(2,2,3,3,-tetrafluoropropyl methacrylate), and poly(2,2,2-trifluoroethyl methacrylate). The light scattering parts 60 may have the refractive index lower than those of the substrate 10 and the planarization layer 70. For example, the refractive index of the light scattering parts 60 may be about 1.3.

The light scattering parts 60 may improve an internal light extraction efficiency of the organic light emitting device 1. Light generated from the organic light emitting layer 30 may be partially or totally reflected by the substrate 10 to be guided within the first electrode 20 and the organic light emitting layer 30. The light guided within the first electrode 20 and the organic light emitting layer 30 may not be outputted to the substrate 10. The light guided within the first electrode 20 and the organic light emitting layer 30 may be about 45% of the entire amount of the light generated from the organic light emitting layer 30. The light scattering parts 60 may output the light guided within the first electrode 20 and the organic light emitting layer 30 by the reflection to the substrate 10.

The light scattering parts 60 may have the irregular island-shapes. In other words, the shapes of the light scattering parts 60 may be irregular, sizes (e.g., diameters and heights) of the light scattering parts 60 may be irregular, and/or the light scattering parts 60 may be irregularly arranged. The light scattering parts 60 may include a hemisphere-shape, a pillar-shape, an ellipse-shape, and/or a capsule-shape. The light scattering parts 60 may have an average diameter within a range of about 100 nm to about 1000 nm.

FIG. 2 is a scanning electron microscopy (SEM) photograph of light scattering parts disposed on a substrate according to some embodiments of the inventive concept.

Referring to FIG. 2, the light scattering parts 60 having the irregular island-shapes were observed. The light scattering parts 60 are irregularly distributed on the substrate in island-shape.

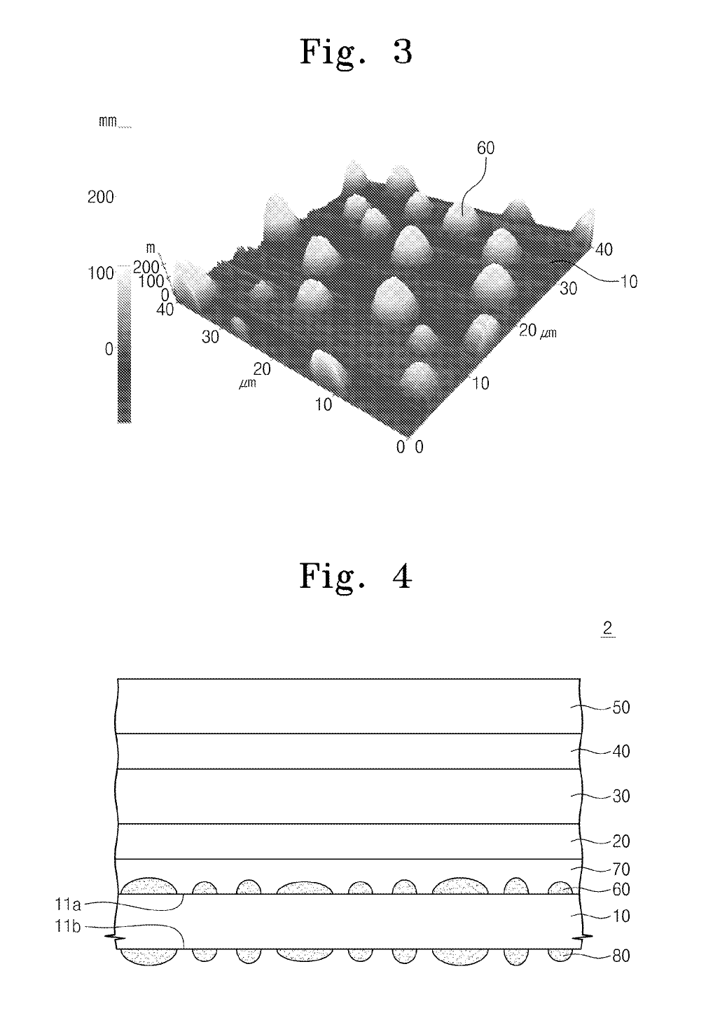

FIG. 3 is an atomic force microscopy (AFM) image of light scattering parts disposed on a substrate according to some embodiments of the inventive concept. Referring to FIG. 3, the light scattering parts 60 having the irregular island-shapes were observed. The light scattering parts 60 are irregularly distributed. The light scattering parts 60 may have irregular shapes, irregular diameters, and/or irregular heights. The light scattering parts 60 may have the average diameter of about 4.7 μm. The light scattering parts 60 may have an average height of about 200 nm. The average diameter and/or the average height of the light scattering parts 60 may be controlled.

Referring to FIG. 1 again, the planarization layer 70 may cover the light scattering parts 60. The planarization layer 70 may include a transparent material. Additionally, the planarization layer 70 may be formed of a material having a high refractive index. The planarization layer 70 may be formed of an inorganic material, a polymer material, and/or any combination thereof. The planarization layer 70 may have a refractive index similar to or greater than the refractive index of the first electrode 20. For example, the planarization layer 70 may have the refractive index within a range of about 1.8 to about 2.5.

The planarization layer 70 may planarize an upper region on the light scattering parts 60. The planarization layer 70 may protect the light scattering parts 60 of the irregular island-shapes. The organic light emitting device 1 may have a thickness of several hundreds nm. Thus, the planarization layer 70 may provide a top surface having a surface roughness of several nm or less. Thus, electrical characteristics of the organic light emitting device 1 including the light scattering parts 60 may not deteriorated as compared with an organic light emitting device not including the light scattering parts 60.

The first electrode 20 may be disposed on the planarization layer 70. The first electrode 20 may be an anode electrode. The first electrode 20 may be applied with a voltage from an external system, so as to provide holes into the organic light emitting layer 30. The first electrode 20 may transmit light. The first electrode 20 may include a transparent conductive oxide (TCO). The refractive index of the first electrode 20 may be greater than the refractive index of the substrate 10. The first electrode 20 may have the refractive index within a range of about 1.6 to about 1.9. For example, the first electrode 20 may have the refractive index of about 1.8.

The organic light emitting layer 30 may be disposed on the first electrode 20. The organic light emitting layer 30 may generate the light by recombination of holes and electrons supplied from the first and second electrodes 20 and 40. The organic light emitting layer 30 may be a single-layer or a multi-layer including an assistant layer. The organic light emitting layer 30 may further include the assistant layer capable of improving light emitting efficiency. The assistant layer may include at least one of a hole injecting layer, a hole transfer layer, an electron transfer layer, and an electron injecting layer.

The organic light emitting layer 30 may include at least one of organic light emitting materials. In some embodiments, the organic light emitting material of the organic light emitting layer 30 may be doped with dopants. The organic light emitting layer 30 may have the refractive index within a range of about 1.6 to about 1.9. For example, the organic light emitting layer 30 may have the refractive index of about 1.75.

The second electrode 40 may be disposed on the organic light emitting layer 30. The second electrode 40 may be a cathode. The second electrode 40 may include a conductive material. The second electrode 40 may include a conductive material having a work function lower than that of the first electrode 20. The second electrode 40 may be applied with a voltage from the external system, so as to apply electrons to the organic light emitting layer 30. The second electrode 20 may reflect the light generated from the organic light emitting layer 30 toward the first electrode 20.

The encapsulation layer 50 may be disposed on the second electrode 40. The encapsulation layer 50 may be a sealing encapsulation layer or a packaged glass plate. The encapsulation layer 50 may be formed of an air-impermeable material. Additionally, the encapsulation layer 50 may be transparent. The encapsulation layer 50 may protect the organic light emitting layer 30.

FIG. 4 is a cross-sectional view illustrating an organic light emitting device according to other embodiments of the inventive concept.

Referring to FIG. 4, an organic light emitting device 2 according to the present embodiment may include the light scattering parts 60 in contact with a first surface 11a of the substrate 10, antireflective parts 80 in contact with a second surface 11b of the substrate 10, the planarization layer 70, the first electrode, 20, the organic light emitting layer 30, the second electrode 40, and the encapsulation layer 50. The planarization layer 70 may be disposed on the first surface 11a of the substrate 10 to cover the light scattering parts 60. The first electrode 20, the organic light emitting layer 30, the second electrode 40, and the encapsulation layer 50 may be sequentially stacked on the planarization layer 70.

The substrate 10 may include the first surface 11a and the second surface 11b opposite to each other. As described above, the first surface 11a of the substrate 10 may be in contact with the light scattering parts 60, and the second surface 11b of the substrate 10 may be in contact with the antireflective parts 80. The substrate 10 may be a transparent substrate. The substrate 10 may include an inorganic material such as silicon or silicon oxide, and/or an organic material such as polyimide. The substrate 10 including silicon oxide may have the refractive index within a range of about 1.4 to about 1.6.

The light scattering parts 60 may be disposed between the substrate 10 and the first electrode 20. The light scattering parts 60 may include an organic material having a low refractive index. The organic material may be an oligomer or polymer including fluorine (e.g., a polyfluorine-based material). For example, the organic material may include at least one of poly(1,1,1,3,3,3-hexafluoroisopropyl acrylate), poly(2,2,3,3,4,4,4-heptafluorobutyl acrylate), poly(2,2,3,3,4,4,4-heptagluorobutyl methacrylate), poly(2,2,3,3,3-pentafluoropropyl acrylate), poly(1,1,1,3,3,3-hexafluoroisopropyl methacrylate), poly(2,2,3,4,4,4-hexafluorobutyl acrylate), poly(2,2,3,4,4,4-hexafluorobutyl methacrylate), poly(2,2,3,3,3-pentafluoropropyl methacrylate), poly(2,2,2-trifluropropyl methacrylate), poly(2,2,2-trifluoroethyl acrylate), poly(2,2,3,3-tetrafluoropropryl acrylate), poly(2,2,3,3,-tetrafluoropropyl methacrylate), and poly(2,2,2-trifluoroethyl methacrylate). The light scattering parts 60 may have the refractive index lower than those of the substrate 10 and the planarization layer 70. For example, the refractive index of the light scattering parts 60 may be about 1.3.

The light scattering parts 60 may improve an internal light extraction efficiency of the organic light emitting device 1. The light scattering parts 60 may output the light guided within the first electrode 20 and the organic light emitting layer 30 by the reflection to the substrate 10.

The light scattering parts 60 may have the irregular island-shapes. In other words, the shapes of the light scattering parts 60 may be irregular, sizes (e.g., diameters and heights) of the light scattering parts 60 may be irregular, and/or the light scattering parts 60 may be irregularly arranged. The light scattering parts 60 may include a hemisphere-shape, a pillar-shape, an ellipse-shape, and/or a capsule-shape. The light scattering parts 60 may have an average diameter within a range of about 100 nm to about 1000 nm.

The planarization layer 70 may be disposed on the first surface 11 a of the substrate 10 to cover the light scattering parts 60. The planarization layer 70 may include a transparent material. Additionally, the planarization layer 70 may be formed of a material having a high refractive index. The planarization layer 70 may be formed of an inorganic material, a polymer material, and/or any combination thereof. The planarization layer 70 may have a refractive index similar to or greater than the refractive index of the first electrode 20. As a difference between the refractive indexes of the planarization layer 70 and the first electrode 20 increases, the light extraction efficiency of the organic light emitting device 2 may increase. For example, the planarization layer 70 may have the refractive index within a range of about 1.8 to about 2.5.

The first electrode 20 may be disposed on the planarization layer 70. The first electrode 20 may be an anode electrode. The first electrode 20 may be a transparent electrode transmitting light. The refractive index of the first electrode 20 may be greater than the refractive index of the substrate 10 and smaller than the refractive index of the planarization layer 70. The first electrode 20 may have the refractive index within a range of about 1.6 to about 1.9. For example, the first electrode 20 may have the refractive index of about 1.8.

The organic light emitting layer 30 may be disposed on the first electrode 20. The organic light emitting layer 30 may be a single-layer or a multi-layer including an assistant layer. The organic light emitting layer 30 may further include the assistant layer capable of improving light emitting efficiency. The assistant layer may include at least one of a hole injecting layer, a hole transfer layer, an electron transfer layer, and an electron injecting layer. The organic light emitting layer 30 may include at least one of organic light emitting materials. The organic light emitting material of the organic light emitting layer 30 may be doped with dopants. The organic light emitting layer 30 may have a refractive index smaller than that of the first electrode 20. The organic light emitting layer 30 may have the refractive index within a range of about 1.6 to about 1.9. For example, the organic light emitting layer 30 may have the refractive index of about 1.75.

The second electrode 40 may be disposed on the organic light emitting layer 30. The second electrode 40 may be a cathode. The second electrode 40 may include a conductive material.

The encapsulation layer 50 may be disposed on the second electrode 40. The encapsulation layer 50 may be formed of an air-impermeable material. Additionally, the encapsulation layer 50 may be transparent. The encapsulation layer 50 may cover the organic light emitting device 2. The second electrode 40 may reflect the light generated from the organic light emitting layer 30 toward the first electrode 20.

The antireflective parts 80 may be in contact with the second surface 11b of the substrate 10. The antireflective parts 80 may include the same material and/or structure as or a similar material and/or structure to the light scattering parts 60. For example, the antireflective parts 80 may include an organic material having a low refractive index. The antireflective parts 80 may have irregular island-shapes. In other words, the shapes of the antireflective parts 80 may be irregular, sizes (e.g., diameters and heights) of the antireflective parts 80 may be irregular, and/or the antireflective parts 80 may be irregularly arranged. The antireflective parts 80 may improve external light extraction. The antireflective parts 80 may output the light confined in the substrate 10 to the outside of the organic light emitting device 1.

A planarization layer may not be provided on the antireflective parts 80.

An operating principle of the organic light emitting device according to embodiments of the inventive concept will be described with reference to FIG. 4.

Referring to FIG. 4, electrons and holes may be combined with each other to form excitons in the organic light emitting layer. The generated excitons may be transited to a bottom state, such that the organic light emitting device 2 emits light. The holes may be supplied from the first electrode 20 (i.e., the anode). The electrons may be supplied from the second electrode 40 (i.e., the cathode). A portion of the light emitted from the organic light emitting layer 30 may be totally reflected at an interface between layers having the refractive indexes different from each other, such that the reflected light may be guided in each of the layers. Thus, the portion of the light emitted from the organic light emitting layer 30 may not be outputted outside an organic light emitting device. About 20% of the total amount of the emitted light may be outputted outside the device, and about 80% of the total amount of the emitted light may be confined inside the device to be lost.

According to embodiments of the inventive concept, the light extraction efficiency of the organic light emitting device 2 may be improved by the difference between the refractive indexes of the organic light emitting layer 30, the first electrode 20 and/or the planarization layer 70. The light generated from the organic light emitting layer 30 may be incident on the first electrode 20 and the planarization layer 70 and then be outputted outside the organic light emitting device 2. The light emitted from the organic light emitting layer 30 may follow Snell's law. The Snell's law is expressed by the following equation 1.

n1/n2=sin a2/sin a1 [Equation 1]

wherein, “n1” denotes the refractive index of the organic light emitting layer 30, “n2” denotes the refractive index of the first electrode 20, “a1” denotes an incidence angle of the light, and “a2” denotes an refraction angle of the light. The refractive index of the first electrode 20 may be greater than the refractive index of the organic light emitting layer 30. When the light generated from the organic light emitting layer 30 is incident on the substrate 10, the refractive angle of the light may be smaller than the incidence angle of the light. Thus, it is possible to minimize loss of the portions of the light emitted from the organic light emitting layer 30 which is caused at the interface between the organic light emitting layer 30 and the first electrode 20 by the total reflection. The planarization layer 70 may have the greater refractive index than the first electrode 20. Thus, it is possible to minimize loss of the light caused at the interface between the first electrode 20 and the planarization layer 70 by the reflection.

Additionally, the light extraction efficiency of the organic light emitting device 2 may be improved by the light scattering parts 60 of the irregular island-shapes.

The light scattering parts 60 may be provided between the substrate 10 and the planarization layer 70. The light scattering parts 60 may have the refractive index smaller than that of the substrate 10. For example, the light scattering parts 60 may have the refractive index of about 1.3, and the substrate 10 may have the refractive index of about 1.5. Thus, the light reflected by interfaces between the substrate 10 and the light scattering parts 60 may be minimized by the difference between the refractive indexes of the substrate 10 and the light scattering parts 60.

The light scattering parts 60 may have the irregular island-shapes. The low refractive index-material of the light scattering parts 60 and the high refractive index-material of the planarization layer 70 may constitute an interface in wavelength scale. The interface of the wavelength scale may function as a light scattering element. The light may be scattered, irregularly reflected, refracted, and/or diffracted by the light scattering parts 60, so as to be outputted to the substrate 10, not the inside of the first electrode 20. Thus, a ratio of the light outside the substrate 10 to the light reflected into the first electrode 20 may increase.

Light scattering parts having regular patterns may improve light extraction efficiency of light having a specific wavelength. However, since the light scattering parts 60 have irregular shapes, irregular sizes (e.g., irregular heights, irregular diameters), and irregular arrangement, the entire light of a visible ray band may be scattered, irregularly reflected, refracted, and/diffracted without dependence on a specific wavelength. Thus, the light extraction efficiency of the organic light emitting device 2 may be improved. An organic white light emitting device may have greater brightness than other organic light emitting devices of other colors. The organic white light emitting device may require high light extraction efficiency. The light scattering parts 60 may effectively improve light extraction efficiency of the white light.

The antireflective parts 80 may be in contact with the second surface 11b of the substrate 10, so as to be disposed outside the organic light emitting device 2.

A substrate mode light may be incident on an interface between the substrate 10 and the air at an angle greater than a critical angle with respect to a normal line to the surface of the substrate. Thus, the substrate mode light may be totally reflected at the interface between the substrate 10 and then be confined in the substrate 10 to be lost. The antireflective parts 80 may output the substrate mode light outside the substrate 10 to improve the external light extraction efficiency of the organic light emitting device 2.

Methods of fabricating an organic light emitting device according to embodiments will be described hereinafter.

### First Embodiment

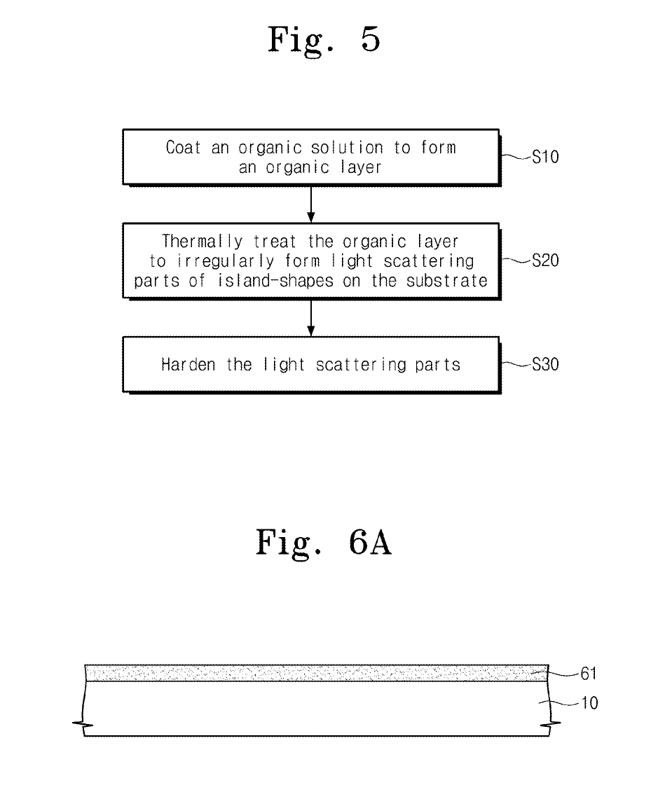

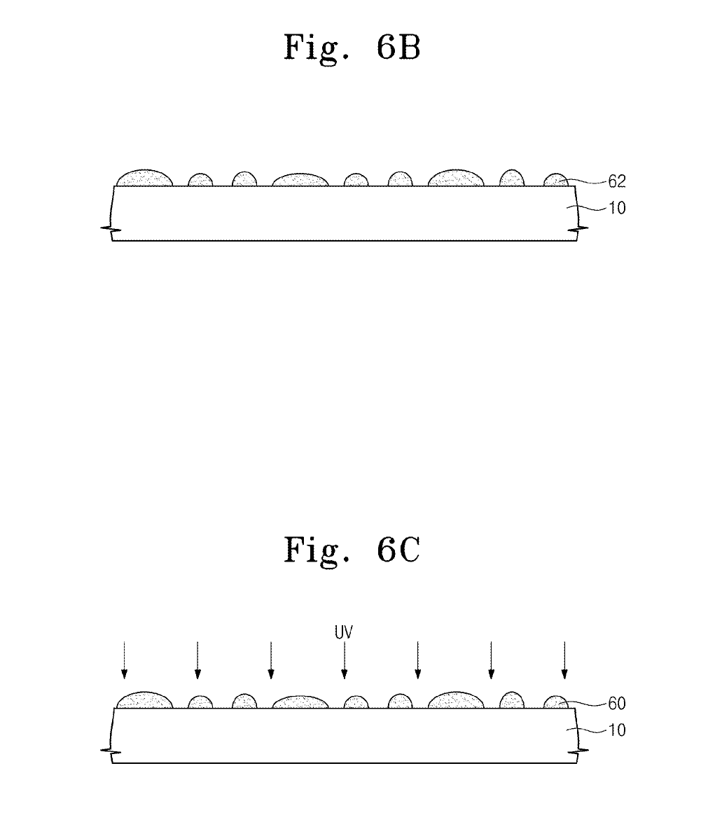

FIG. 5 is a flowchart illustrating a method of fabricating light scattering parts according to a first embodiment of the inventive concept. FIGS. 6A, 6B, and 6C are cross-sectional views illustrating a method of fabricating light scattering parts according to a first embodiment of the inventive concept.

Referring to FIG. 5, a method of fabricating light scattering parts may include forming an organic layer on a substrate (S10), thermally treating the organic layer to irregularly form light scattering parts of island-shapes (S20), and crosslinking the light scattering parts (S30).

Referring to FIGS. 5 and 6A, an organic solution including an organic material and a photo cross-linking agent may be coated on one surface of the substrate 10 to form the organic layer 61 (S10). Before the organic solution is coated, the substrate 10 may be cleaned. The cleaning process of the substrate 10 may be performed using deionized water, an organic solvent, a base solution, and/or an acid solution.

An oligomer or polymer including fluorine, a photo initiator, and a solvent may be mixed with each other to prepare the organic solution for the organic layer 61. An entire portion or a portion of hydrogen of polyolefin having a main chain of carbon-carbon bond may be substituted with fluorine to form the oligomer or polymer including fluorine. The polyolefin having the substituted fluorine may have a refractive index lower than that of polyolefin not having the substituted fluorine. Additionally, the polyolefin having the substituted fluorine may be transparent in a visible ray region. The oligomer or polymer including fluorine may be a polyfluorine-based material. For example, the oligomer or polymer including fluorine may include at least one of poly(1,1,1,3,3,3-hexafluoroisopropyl acrylate), poly(2,2,3,3,4,4,4-heptafluorobutyl acrylate), poly(2,2,3,3,4,4,4-heptagluorobutyl methacrylate), poly(2,2,3,3,3-pentafluoropropyl acrylate), poly(1,1,1,3,3, 3-hexafluoroisopropyl methacrylate), poly(2,2,3,4,4,4-hexafluorobutyl acrylate), poly(2,2,3,4,4,4-hexafluorobutyl methacrylate), poly(2,2,3,3,3-pentafluoropropyl methacrylate), poly(2,2,2-trifluropropyl methacrylate), poly(2,2,2-trifluoroethyl acrylate), poly(2,2,3,3-tetrafluoropropryl acrylate), poly(2,2,3,3,-tetrafluoropropyl methacrylate), and poly(2,2,2-trifluoroethyl methacrylate). The oligomer or polymer including fluorine, the photo initiator, and the solvent may be stirred in the mixing process. The stirring process may be performed by a magnetic bar. After the stirring process, a filtering process may be performed. The coating process may be performed by a spin-coating method. A thickness of the organic layer 61 may be controlled.

Referring to FIGS. 5 and 6B, the organic layer 61 may be thermally treated to irregularly form the light scattering parts 62 of the island-shapes on the substrate 10 (S20). The light scattering parts 62 of the island-shapes may be formed by a dewetting phenomenon. The dewetting phenomenon means that a material having a dewetting property is uniformly coated on a surface and then the coated material is formed into irregular patterns having partially concave and/or convex shapes. The organic material including fluorine may have a hydrophobic property. The substrate 10 may have a hydrophilic property. When the substrate 10 is thermally treated or an atmosphere of the substrate 10 is changed, the dewetting phenomenon may occur between the organic material of the hydrophobic property and the substrate 10 of the hydrophilic property. Thus, the light scattering parts 62 of the irregular island-shapes may be formed from the flat coated organic layer 61 of FIG. 6A by the dewetting phenomenon. The thermal treating process may be performed using an oven and/or a hot plate by a thermal annealing process or a rapid thermal annealing (RTA) process. The thermal treating process may be performed at a temperature under a softening point of the substrate 10. For example, the thermal treating process may be performed at a temperature within a range of a room temperature to about 250 degrees Celsius. The atmosphere of the substrate 10 may be changed into an organic solvent vapor atmosphere or a vacuum state. The irregular structure of the light scattering parts 62 may be controlled by the temperature and a process time of the thermal treating process, a thickness of the coated organic solution, a molecular weight of the organic solution, a compositing ratio of the organic solution, a surface treating method of the substrate 10, and/or a dewetting atmosphere. The light scattering parts 62 of the irregular island-shapes may have irregular shapes caused by a surface energy.

Referring to FIGS. 5 and 6C, ultraviolet rays may be irradiated to crosslink the light scattering parts 62, thereby forming light scattering parts 60 (S30). The crosslinked light scattering parts 60 may be stabilized. The organic solution, the organic layer, and the light scattering parts 62 before the crosslinking process may be stored in a container such as a Petri dish surrounded by an opaque wrap in the steps S10 and S20 in order that those are not exposed to light.

### Second Embodiment

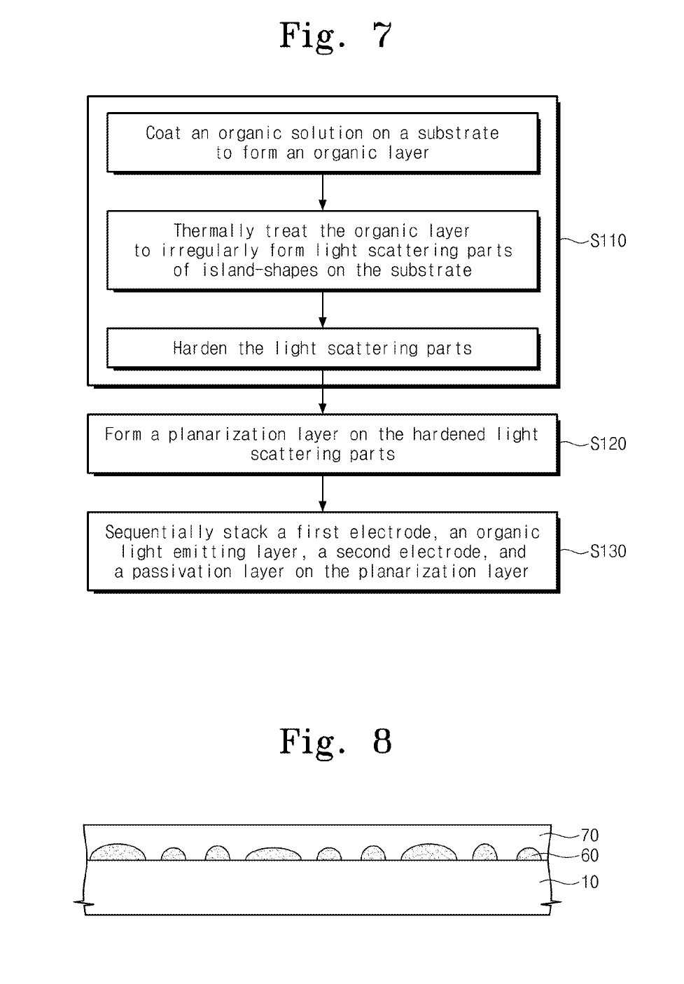

FIG. 7 is a flowchart illustrating a method of fabricating light scattering parts according to a second embodiment of the inventive concept.

Referring to FIGS. 1 and 7, a method of fabricating an organic light emitting device according to a second embodiment may include forming light scattering parts 60 on a substrate 10 (S110), forming a planarization layer 70 on the light scattering parts 60 (S120), and sequentially stacking a first electrode 20, an organic light emitting layer 30, a second electrode 40, and an encapsulation layer 50 on the planarization layer 70 (S130).

Forming the light scattering parts 60 on the substrate 10 (S110) may be performed by the same method as or a similar method to the method of forming the light scattering parts 60 according to the first embodiment.

FIG. 8 is a cross-sectional view illustrating a method of forming a planarization layer according to some embodiments of the inventive concept.

Referring to FIG. 8, the planarization layer 70 may be formed on the light scattering parts 60 (S120). Forming the planarization layer 70 may include coating a precursor on the light scattering parts 60 and crosslinking the coated precursor. The precursor may be a complex of an inorganic material and a polymer. The inorganic material may be prepared using a sol-gel method. The inorganic material may be dispersed in a solvent and then the polymer may be added in the solvent including the inorganic material. The precursor may be coated by a spin-coating process. For example, the precursor may be coated by a deep coating method, a slit coating method, a bar coating method, and/or a spray coating method. A thermal treating process and/or irradiation of ultraviolet rays may be performed on the coated precursor layer to crosslink the coated precursor layer.

The first electrode 20, the organic light emitting layer 30, the second electrode 40, and the encapsulation layer 50 may be sequentially formed on the planarization layer 70 (S130).

### Third Embodiment

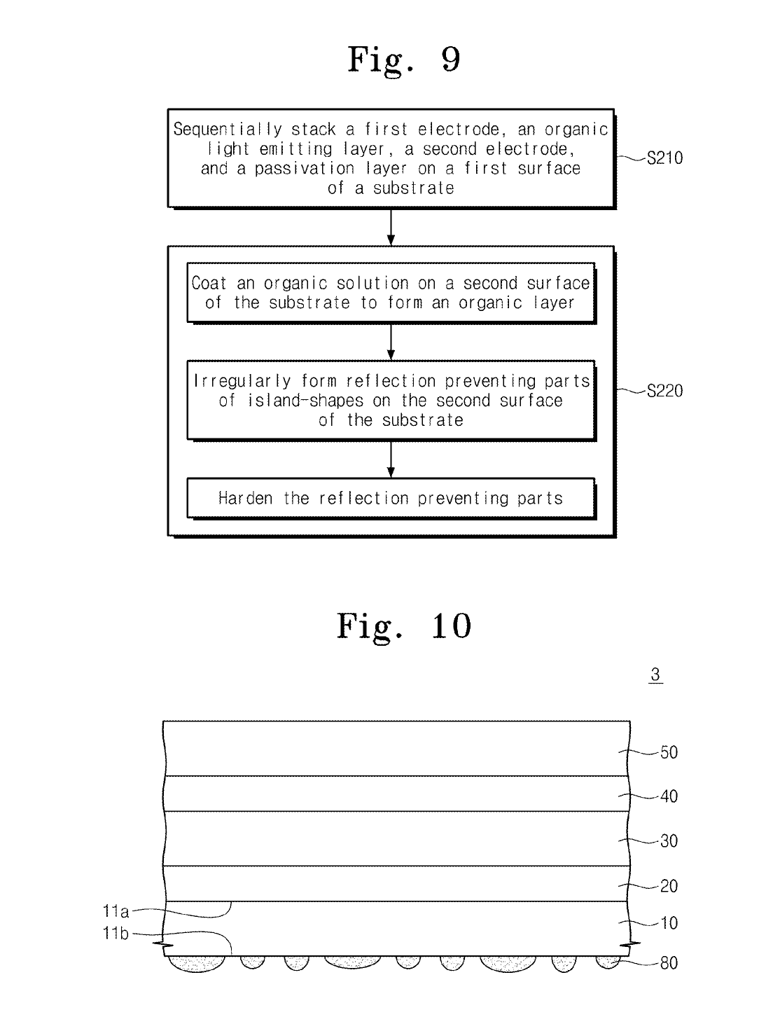

FIG. 9 is a flowchart illustrating a method of fabricating light scattering parts according to a third embodiment of the inventive concept. FIG. 10 is a cross-sectional view illustrating a method of fabricating light scattering parts according to a third embodiment of the inventive concept.

Referring to FIGS. 9 and 10, a method of fabricating an organic light emitting device 3 according to a third embodiment may include sequentially forming a first electrode 20, an organic light emitting layer 30, a second electrode 40, and an encapsulation layer 50 on a first surface 11a of a substrate 10 (S210), and forming antireflective parts 80 on a second surface 11b of the substrate 10 (S220).

Forming the antireflective parts 80 on the second surface 11b of the substrate 10 (S220) may include loading the organic light emitting device 3 on a spin coater, and forming the antireflective parts 80 on the loaded organic light emitting device 3. When the organic light emitting device 3 is loaded on the spin coater, the second surface 11b of the substrate faces upward. The antireflective parts 80 may be formed on the second surface 11b of the substrate 10 of the loaded organic light emitting device 3. Forming the antireflective parts 80 may include coating an organic solution on the second surface 11b of the substrate to form an organic layer, irregularly forming antireflective parts of island-shapes on the second surface 11b of the substrate, and crosslinking the antireflective parts. The organic solution for the antireflective parts 80 may be the same as or similar to the organic solution for the light scattering parts 60 described in the first embodiment. A thermal treating process for irregularly forming the antireflective parts of the island-shapes may be the same as or similar to the thermal treating process for the light scattering parts 60 described in the first embodiment. Additionally, the method of crosslinking the antireflective parts may be the same as or similar to the method of crosslinking the light scattering parts described in the first embodiment.

### Fourth Embodiment

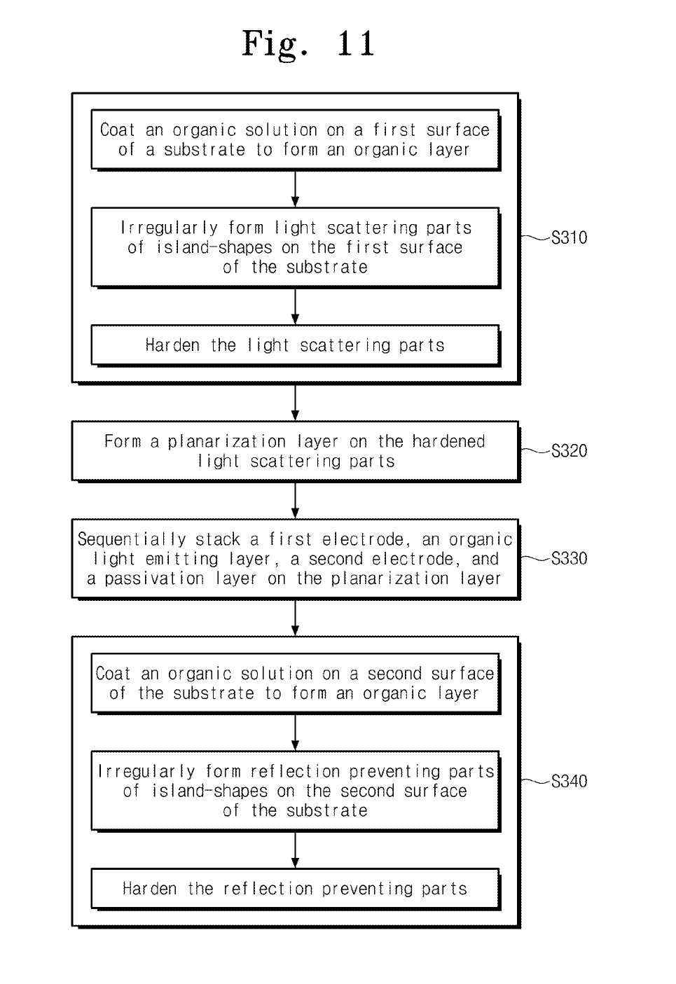

FIG. 11 is a flowchart illustrating a method of fabricating light scattering parts according to a fourth embodiment of the inventive concept.

Referring to FIGS. 5 and 11, a method of fabricating an organic light emitting device according to a fourth embodiment may include forming light scattering parts 60 on a first surface 11a of the substrate 10 (S310), forming a planarization layer 70 on the light scattering parts 60 (S320), sequentially forming a first electrode 20, an organic light emitting layer 30, a second electrode 40, and an encapsulation layer 50 on the planarization layer 70 (S330), and forming antireflective parts 80 on a second surface 11b of the substrate 10 (S340).

The steps S310, S320, and S330 may be the same as or similar to the steps S110, S120, and S130 described in the second embodiment.

Forming the antireflective parts 80 on the second surface 11b of the substrate 10 (S340) may include loading the organic light emitting device on a spin coater, and forming the antireflective parts 80 on the loaded organic light emitting device. When the organic light emitting device is loaded on the spin coater, the second surface 11b of the substrate 10 faces upward. The antireflective parts 80 may be formed on the second surface 11b of the substrate 10 of the loaded organic light emitting device. The method of forming the antireflective parts 80 may be the same as or similar to the method described in the third embodiment.

According to embodiments of the inventive concept, the light scattering parts may be formed to have island-shapes of irregular sizes and irregular arrangement. The light scattering parts may be formed using the organic solution having the low refractive index by the dewetting phenomenon. The dewetting phenomenon may occur at the low temperature within the range of the room temperature to about 250 degree Celsius. Thus, the light scattering parts may be formed not to influence other elements of the organic light emitting device and be applied to the organic white light emitting device including the plastic substrate. The light scattering parts of the irregular island-shapes may be stabilized by the photo crosslinking process. The light scattering parts may have stability with respect to heat and/or chemicals used in the method of fabricating the organic light emitting device. Additionally, additional process etching the substrate and/or the light scattering parts may not be required for forming the light scattering parts. Thus, the organic light emitting device may be fabricated inexpensively and be applied to various organic/inorganic substrates. The organic white light emitting device may be effectively fabricated by the method of fabricating the organic light emitting device according to embodiments of the inventive concept.

According to embodiments of the inventive concept, the organic light emitting device may include the light scattering parts of the irregular island-shapes. The light scattering parts may have the low refractive index to improve the light extraction efficiency of the organic light emitting device. Additionally, the light scattering parts of the irregular island-shapes may improve the light extraction efficiency of lights of all wavelengths, so as to be applied to the organic white light emitting device.

The light scattering parts of the irregular island-shapes may be formed from the organic solution by the dewetting phenomenon. The light scattering parts may be formed at the temperature within the range of the room temperature to about 250. As a result, the organic light emitting device may be easily and simply fabricated to reduce fabricating costs of the organic light emitting device and to be suitable to mass-production. Additionally, the light scattering parts may be formed on one various substrates. Thus, the organic white light emitting device may be effectively fabricated by the light scattering parts.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. An organic light emitting device comprising:
a substrate including a first surface and a second surface opposite to each other and having a first refractive index;
light scattering parts disposed on the first surface of the substrate and having a second refractive index;
a planarization layer disposed on the light scattering parts and having a third refractive index;
a first electrode disposed on the planarization layer;
an organic light emitting layer disposed on the first electrode;
a second electrode disposed on the organic light emitting layer; and
an encapsulation layer disposed on the second electrode,
wherein the light scattering parts have irregular island-shapes irregularly arranged; and
wherein the second refractive index is smaller than each of the first refractive index and the third refractive index.

2. The organic light emitting device of claim 1, further comprising:
antireflective parts disposed on the second surface of the substrate,
wherein the antireflective parts have a refractive index smaller than the first refractive index;
wherein the antireflective parts have irregular island-shapes irregularly arranged; and
wherein the island-shapes of the antireflective parts include at least one of a hemisphere-shape, a pillar-shape, an ellipse-shape, and/or a capsule-shape.

3. The organic light emitting device of claim 2, wherein the antireflective parts include a polyfluorine-based material.

4. The organic light emitting device of claim 1, wherein the light scattering parts include a polyfluorine-based material.

5. The organic light emitting device of claim 1, wherein the first electrode has a same or greater refractive index than the organic light emitting layer; and
wherein the third refractive index is greater than the refractive index of the first electrode.

6. The organic light emitting device of claim 1, wherein an average diameter of the light scattering parts has a range of about 100 nm to about 1000 nm.

7. A method of fabricating an organic light emitting device, comprising:
coating an organic solution including an organic material and a photo cross-linking agent on a first surface of a substrate to form an organic layer;
thermally treating the organic layer to irregularly form light scattering parts of island-shapes on the first surface of the substrate; and
crosslinking the light scattering parts.

8. The method of claim 7, further comprising:
forming a planarization layer on the crosslinked light scattering parts.

9. The method of claim 8, further comprising:
sequentially stacking a first electrode, an organic light emitting layer, a second electrode, and an encapsulation layer on the planarization layer.

10. The method of claim 8, wherein forming the planarization layer comprises:
spin-coating a precursor on the crosslinked light scattering parts; and
crosslinking the spin-coated precursor by a thermal or UV exposure process.

11. The method of claim 7, further comprising:
forming antireflective parts on a second surface opposite to the first surface of the substrate.

12. The method of claim 11, wherein forming the antireflective parts comprises:
coating an organic solution including an organic material and a photo cross-linking agent on the second surface of a substrate to form an organic layer;
thermally treating the organic layer disposed on the second surface to irregularly form antireflective parts of island-shapes on the second surface of the substrate; and
crosslinking the antireflective parts.

13. The method of claim 7, wherein the organic material has a hydrophobic property;
wherein the substrate has a hydrophilic property; and
wherein the light scattering parts are formed using a dewetting phenomenon of the hydrophobic organic material and the hydrophilic substrate.

14. The method of claim 7, wherein the light scattering parts are formed by a thermal treating process performed at a temperature of about 250° C. or less.

15. A method of fabricating an organic light emitting device, comprising:
providing a substrate including a first surface and a second surface opposite to each other;
sequentially stacking a first electrode, an organic light emitting layer, a second electrode, and an encapsulation layer on the first surface of the substrate; and
forming antireflective parts on the second surface of the substrate,
wherein forming the antireflective parts comprises:
coating an organic solution including an organic material and a photo cross-linking agent on the second surface of a substrate to form an organic layer;
thermally treating the organic layer to irregularly form antireflective parts of island-shapes on the second surface of the substrate; and
crosslinking the antireflective parts.

16. The method of claim 15, wherein the organic material includes a polyfluorine-based material.

17. The method of claim 15, wherein the antireflective parts are formed by a thermal treating process performed at a temperature of about 250° C. or less.

18. The method of claim 15, wherein the organic material has a hydrophobic property;
wherein the substrate has a hydrophilic property; and
wherein the antireflective parts are formed using a dewetting phenomenon of the hydrophobic organic material and the hydrophilic substrate.
